(19) United States
(12) Patent Application Publication
(10) Pub. No.: US 2026/0363107 A1
(43) Pub. Date: Nov. 12, 2026

(54) Semiconductor Device and Method of Forming Double Peripheral Wall Structure as Barrier to Underfill Material in Optical Packaging

(71) Applicant: STATS ChipPAC Pte. Ltd., Singapore (SG)

(72) Inventors: Linda Pei Ee Chua, Singapore (SG); Swain Hong Alfred Yeo, Singapore (SG); Marites Roque, Singapore (SG)

(73) Assignee: STATS ChipPAC Pte. Ltd., Singapore (SG)

(21) Appl. No.: 19/200,672

(22) Filed: May 7, 2025

(51) Int. Cl. H10W 70/65; H10F 77/50; H10W 72/00; H10W 72/30; H10W 74/01; H10W 74/15; H10W 90/00

(52) U.S. Cl. CPC H10W 70/65; H10W 74/012; H10W 74/15; H10F 77/50; H10W 72/01323; H10W 72/387; H10W 90/724; H10W 90/734

(57) ABSTRACT

A semiconductor device has an electrical component with an optical region formed on the electrical component. A first barrier is formed proximate to the optical region. A second barrier formed on the interconnect structure, wherein the electrical component is disposed over an interconnect structure. An underfill material is deposited under the electrical component. The first barrier contacts the second barrier to impede the underfill material from reaching the optical region. In particular, the first barrier has a first wall structure and the second barrier has a second wall structure contacting the first wall structure to impede the underfill material from reaching the optical region. The first wall structure may contact a side surface of the second wall structure. A trench can be formed in the second wall structure. The first wall structure can extend into the trench of the second wall structure.

### FIELD OF THE INVENTION

The present invention relates in general to semiconductor devices and, more particularly, to a semiconductor device and method of forming a double peripheral wall structure as a barrier to underfill material from reaching a sensitive area of co-packaged optics (CPO).

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Some semiconductor die utilize a coupler to convert one signal to another signal. For example, a photonic integrated circuit (PIC) uses an optical sensitive area to convert optical data to electrical signals. The PIC must optically communicate with an external optical source and electrically communicate with other semiconductor devices. It would be preferrable to construct the PIC package at the wafer level to simplify the manufacturing procedure and save manufacturing cost. However, PIC integration at the wafer level has been complex, particularly with defects arising from a lack of protection for the optically sensitive area of the semiconductor die. One advantage of PICs is enablement, extending, and increasing data transmission. An application for PICs is integration with ASIC, known as co-packaged optics (CPO), to achieve the goal higher data speed.

In such CPO applications, the semiconductor device also uses various blocks or die to process the electrical signal received from the external light source. These die are often sealed with underfill material. However, underfill material is difficult to control in terms of flow rate and direction, i.e., the underfill bleeding effect. It is important to avoid allowing the underfill material to reach the optical sensitive area, as that would likely cause defects by blocking the optical transmission and reception.

### BRIEF DESCRIPTION OF THE DRAWINGS

FIGS. 1a-1e illustrate a semiconductor wafer with a plurality of semiconductor die separated by a saw street;

FIGS. 2a-2l illustrate a process of forming wall structures to impede underfill material from reaching a sensitive area of a PIC;

FIGS. 3a-3e illustrate another process of forming wall structures to impede underfill material;

FIGS. 4a-4e illustrate yet another process of forming wall structures with a trench to impede underfill material;

FIGS. 5a-5e illustrate yet another process of forming wall structures with a trench to impede underfill material; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

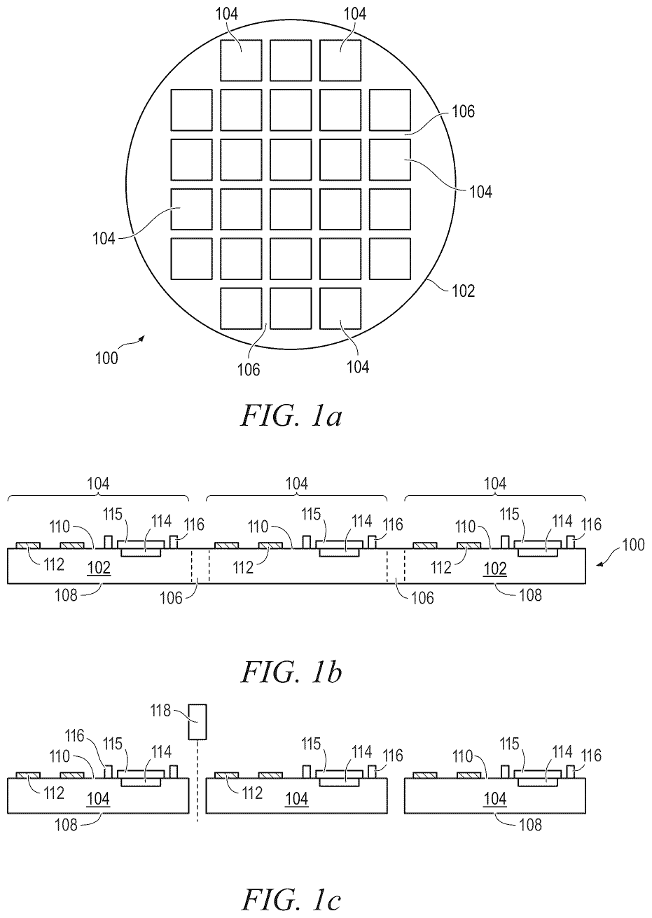

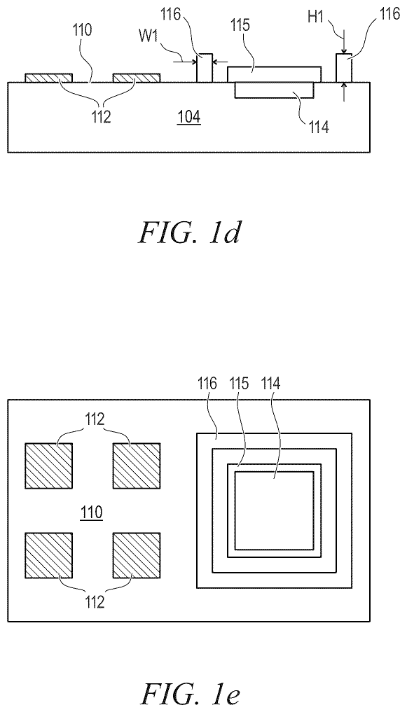

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular or any other geometric shape.

FIG. 1b shows a cross-sectional view of a portion of semiconductor wafer 100. Each semiconductor die 104 has a back or non-active surface 108 and an active layer 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over or within active layer 110a using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads or redistribution layer (RDL) electrically connected to the circuits in active layer 110. Portions of conductive layer 112 can be electrically common or electrically isolated depending on the design and function of semiconductor die 104 within semiconductor wafer 100a and other electrical components.

Each semiconductor die 104a further contains coupler 114. Coupler 114 can have a variety of applications to couple or convert one signal to another signal. In one embodiment, coupler 114 receives light and converts the light to an electrical signal. In that case, coupler 114 is a light sensitive region or optical device, and semiconductor die 104a would be considered a PIC. An optical window 115 is disposed over coupler 114 and bonded to active surface 110. Optical window 115 can be glass or other material capable of passing light.

Wall structure 116 is formed around optical window 115. Wall structure 116 can be one or more layers of SiO2, Si3N4, SiON, Ta2O5, Al2O3, solder resist, PI, BCB, PBO, and other material having similar insulating and structural properties. Wall structure 116 can be formed using PVD, CVD, printing, lamination, spin coating, spray coating, sintering or thermal oxidation. Wall structure 116 can be a masking layer, such as a peripheral PI layer, formed around optical window 115.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

FIG. 1d shows further detail of semiconductor die 104 with wall structure 116 formed around optical window 115. In one embodiment, wall structure 116 has a width W1 of 10-30 micrometers (μm) and height H1 of 15-25 μm. FIG. 1e shows a top view of wall structure 116 extending around optical window 115.

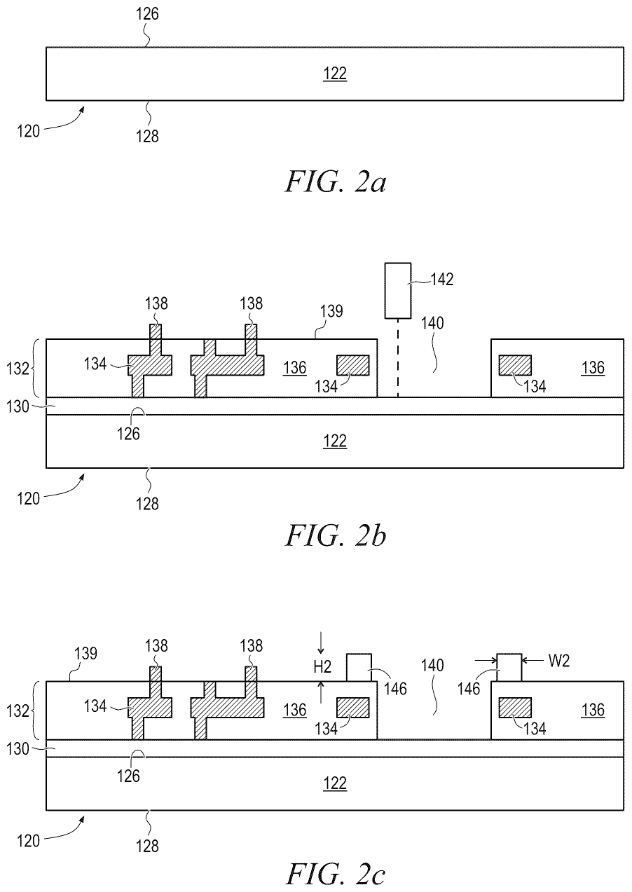

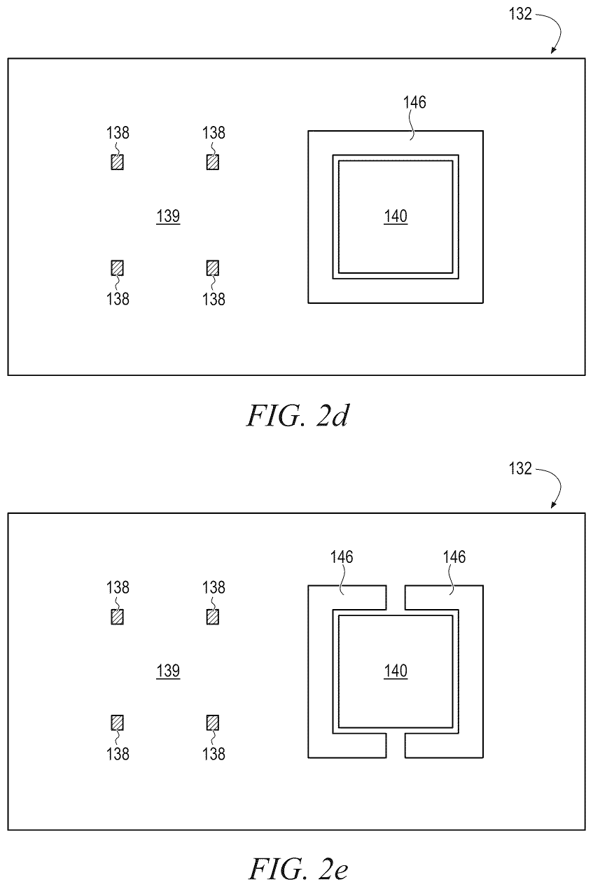

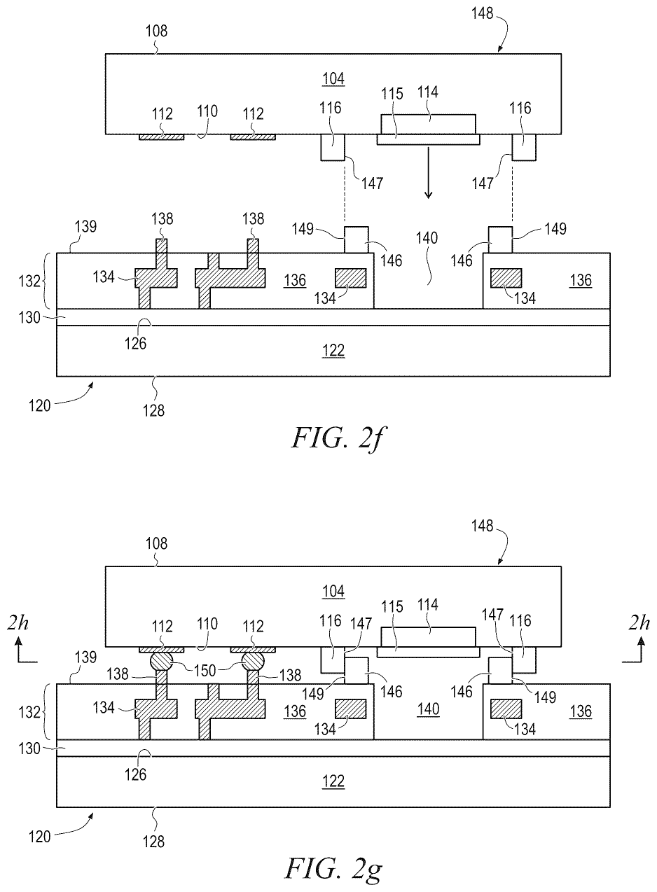

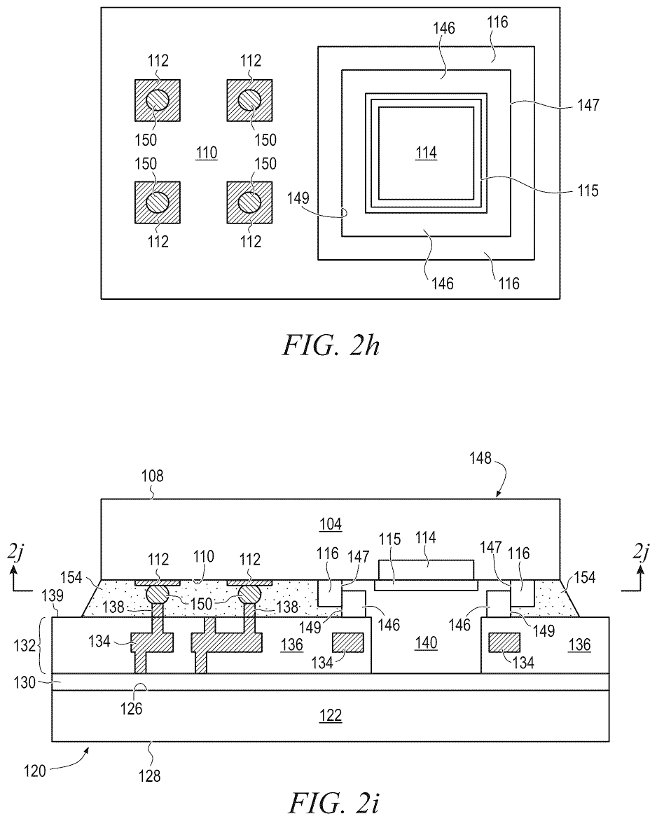

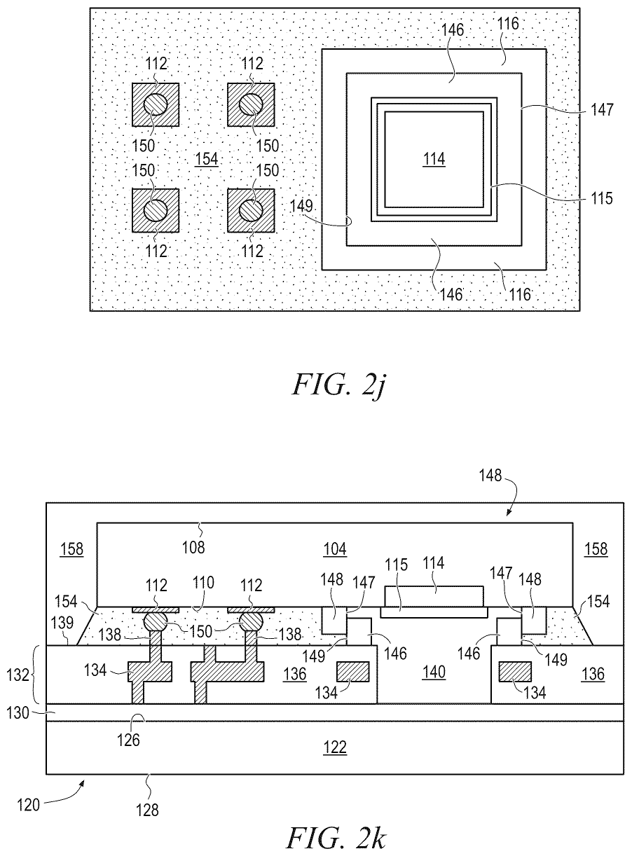

FIG. 2a shows a cross-sectional view of temporary substrate or carrier 120 including core material 122, such as silicon, germanium, aluminum phosphide, aluminum arsenide, gallium arsenide, gallium nitride, indium phosphide, silicon carbide, or other bulk material for structural support. Alternatively, core material 122 can be a multi-layer flexible laminate, ceramic, CCL, or epoxy molding compound. Core material 122 may contain one or more layers of Al, Cu, Sn, Ni, Au, Ag, or other suitable electrically conductive material. Core material 122 may contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Preferably, core material 122 is glass or metal. Substrate 120 has a major surface 126 and major surface 128 opposite surface 126. An adhesive or bonding layer 130 is applied over surface 126.

In FIG. 2b, interconnect structure 132 is formed over surface 126 of substrate 120. Interconnect substrate 132 including one or more conductive layers 134 and one or more insulating layers 136. Conductive layers 134 can be one or more layers of Al, Cu, Sn, Ni, Au, Ag, or other suitable electrically conductive material. Conductive layers 134 can be formed using PVD, CVD, electrolytic plating, electroless plating process, or other suitable metal deposition process. Conductive layers 134 provide horizontal electrical interconnect (such as RDL), and vertical electrical interconnect. Portions of conductive layers 134 can be electrically common or electrically isolated depending on the design and function of electrical components attached thereto. Insulating layers 136 contain one or more layers of SiO2, Si3N4, SiON, Ta2O5, Al2O3, solder resist, PI, BCB, PBO, and other material having similar insulating and structural properties. Insulating layers 136 can be formed using PVD, CVD, printing, lamination, spin coating, spray coating, sintering or thermal oxidation. Insulating layers 136 provide isolation between conductive layers 134. In one embodiment, a first conductive layer 134 is formed, followed by a first insulating layer 136. A second conductive layer 134 is formed over the first insulating layer 136, followed by a second insulating layer 136, and so on. There can be multiple conductive layers like 134 separated by multiple insulating layers 136.

Conductive layer 138 is formed over a portion of conductive layer 134 exposed from surface 139 of interconnect substrate 132. Conductive layers 138 can be one or more layers of Al, Cu, Sn, Ni, Au, Ag, or other suitable electrically conductive material. Conductive layers 138 can be formed using PVD, CVD, electrolytic plating, electroless plating process, or other suitable metal deposition process. In one embodiment, conductive layer 138 is a bump or conductive post.

Alternatively, interconnect structure 132 is a prefabricated structure with conductive layers 134 and 138 and insulating layers 136 bonded to bonding layer 130 over surface 126 of substrate 120.

An opening 140 is formed within interconnect structure 132 extending completely through the interconnect structure to bonding layer 130. Opening 140 can be formed by an etching process or laser direct ablation (LDA) using laser 142.

In FIG. 2c, wall structure 146 is formed around opening 140. Wall structure 146 can be one or more layers of SiO2, Si3N4, SiON, Ta2O5, Al2O3, solder resist, PI, BCB, PBO, and other material having similar insulating and structural properties. Wall structure 146 can be formed using PVD, CVD, printing, lamination, spin coating, spray coating, sintering or thermal oxidation. Wall structure 146 can be a masking layer, such as a peripheral PI layer, formed around opening 140. FIG. 2d shows a top view of wall structure 146 extending around opening 140. Alternatively, FIG. 2e shows a top view of wall structure 146 extending partially around opening 140. In one embodiment, wall structure 146 has a width W2 of 10-30 μm and height H2 of 15-25 μm. Wall structures 116 and 146 act as a barrier, as respectively formed on opposing structures electrical component 148 and interconnect substrate 120, to impede or block later-deposited underfill material from seeping into opening 140 and reaching optical window 115 or optically sensitive area 114.

In FIG. 2f, electrical component 148 is positioned over interconnect structure 132 using a pick and place operation with optical window 115 and wall structure 116 oriented toward opening 140 and wall structure 146. Electrical component 148 is made similar to semiconductor die 104 from FIG. 1c, as a PIC with optical coupler 114 and optical window 115 and wall structure 116. Alternatively, electrical component 148 can include other semiconductor die, semiconductor packages, surface mount devices, discrete electrical devices, or IPDs. In this case, inside side surface 147 of wall structure 116 is aligned with outside side surface 149 of wall structure 146. In FIG. 2g, electrical component 148 is brought into contact with interconnect structure 132, such that inside side surface 147 of wall structure 116 contacts outside side surface 149 of wall structure 146, with conductive layer 112 mechanically and electrically connected to conductive layer 138 by reflowing bumps or conductive paste 150. FIG. 2h is a top view of inside side surface 147 of wall structure 116 contacting outside side surface 149 of wall structure 146 around optical window 115.

In FIG. 2i, underfill material 154, such as epoxy resin, is deposited between electrical component 148 and interconnect substrate 132. The dispensing of underfill material 154 can be difficult to control. Any excess underfill material 154 flows outwardly from the perimeter of electrical component 148, including toward opening 140. Underfill material 154 should not be allowed to reach optical window 115, or optical coupler 114, as that event could cause defects. In this case, wall structure 116 contacting wall structure 146 acts as a barrier to impede or block excess underfill material 154 from reaching optical window 115, or optical coupler 114. Optical window 115 should remain free from dust and contamination from underfill material 154. To achieve the protection for optical window 115, the excess underfill material 154 is impeded or blocked by the combination of wall structure 116 and wall structure 146 from reaching the optical window. FIG. 2j is a top view showing wall structures 116 and 146 proximate to opening 140 as the underfill barrier impeding or blocking excess underfill material 154 from reaching opening 140 and optical window 115.

In FIG. 2k, an encapsulant or molding compound 158 is deposited over and around electrical components 148 and interconnect structure 132 using a paste printing, compressive molding, transfer molding, liquid encapsulant molding, vacuum lamination, spin coating, or other suitable applicator. Encapsulant 158 can be polymer composite material, such as epoxy resin with filler, epoxy acrylate with filler, or polymer with proper filler. Encapsulant 158 is non-conductive, provides structural support, and environmentally protects the semiconductor device from external elements and contaminants.

In FIG. 2l, temporary substrate or carrier 120 and adhesive layer 130 are removed by chemical etching, chemical mechanical polishing (CMP), mechanical peel-off, mechanical grinding, thermal bake, ultra-violet (UV) light, or wet stripping to expose opening 140. Optical cable 160 is disposed within opening 140 to provide light 164 to optical window 115 and coupler 114. Any excess underfill material 154 flows outward from electrical assembly 148. Underfill material 154 should not be allowed to reach optical window 115, as that event could cause defects. In this case, the dual peripheral wall structures 116 and 146 act as a barrier to impede or block excess underfill material 154 from reaching opening 140 and optical window 115. Wall structures 116 and 146 form a keep-out-zone (KOZ) with respect to optical window 115. Note that wall structure 116 is formed on electrical device 148 and wall structure 146 is formed on interconnect structure 132. Accordingly, wall structures 116 and 146 are respectively formed on opposing electrical device 148 and interconnect structure 132. It is the dual peripheral wall structures 116 and 146, as lithography formed on opposing structures, that comes together to form the KOZ. Wall structures 116 and 146 are considered a side-by-side peripheral barrier. Wall structure 116 may be higher or lower than wall structure 146, provided surfaces 147 and 149 make contact to act as the barrier to impede or block excess underfill material 154 from reaching opening 140 and optical window 115.

The combination of interconnect substrate 120, electrical component 148, underfill material 154, and encapsulant 158 constitutes CPO 168. Underfill material 154 is shown as being impeded by wall structures 116 and 146 proximate to opening 140 and optical window 115, i.e., the barrier to impede or block progression of the underfill material toward the opening and optical window, in CPO 168. The underfill barrier provided by wall structures 116 and 146 protects coupler 114 and optical window 115 from damage and defects potentially caused by the bleeding of excess underfill material 154. The underfill barrier increases process margin, capability, and yield, while reducing manufacturing costs.

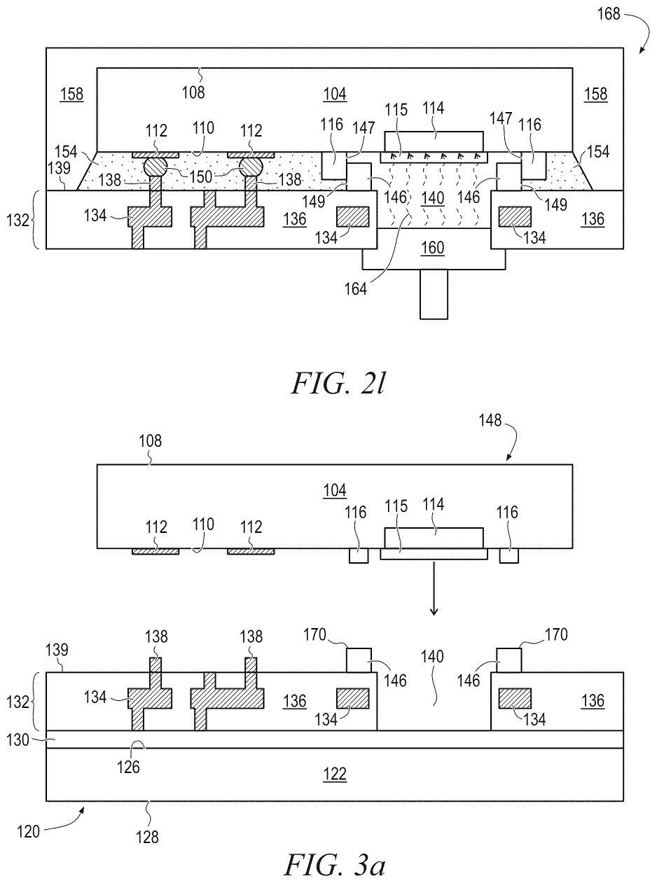

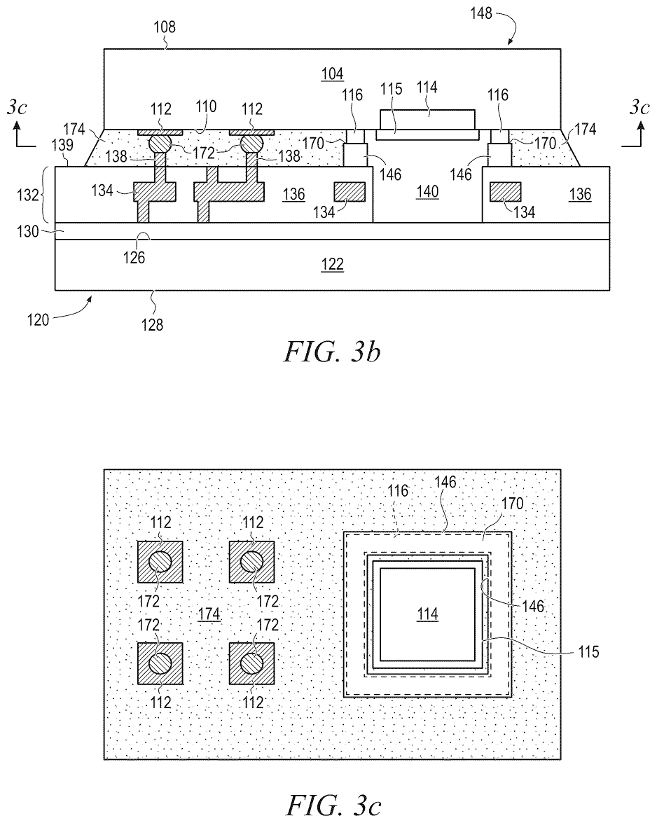

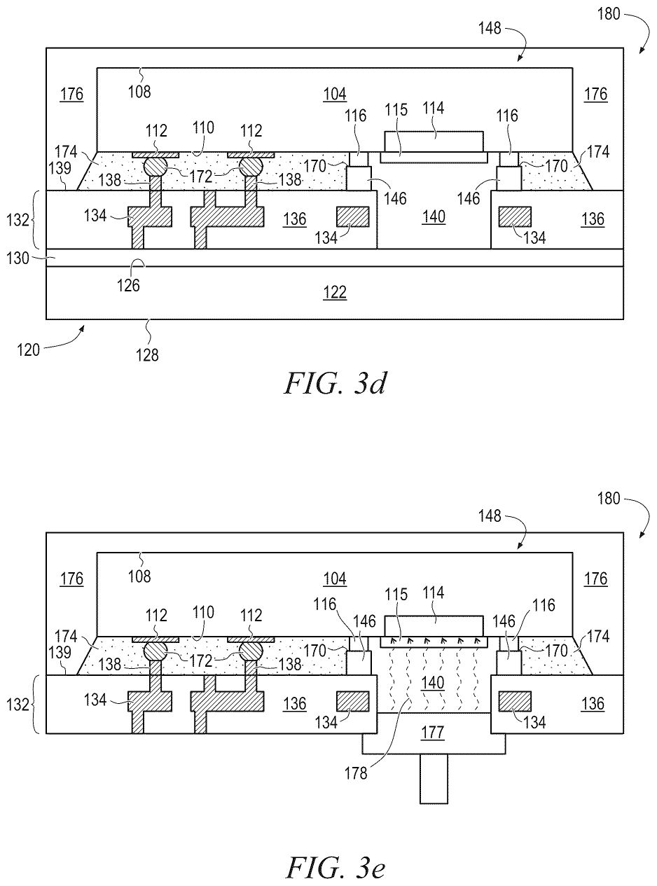

In another embodiment, continuing from FIG. 2f, wall structure 116 is aligned with wall structure 146, as shown in FIG. 3a. Components having a similar function are assigned the same reference number. Electrical component 148 is positioned over interconnect structure 132 using a pick and place operation with optical window 115 and wall structure 116 oriented toward opening 140 and wall structure 146. Electrical component 148 is made similar to semiconductor die 104 from FIG. 1c, as a PIC with optical coupler 114 and optical window 115 and wall structure 116. Alternatively, electrical component 148 can include other semiconductor die, semiconductor packages, surface mount devices, discrete electrical devices, or IPDs. In this case, wall structure 116 is positioned to be aligned directly over a center portion of surface 170 of wall structure 146. In FIG. 3b, electrical component 148 is brought into contact with interconnect structure 132, such that a bottom surface of wall structure 116 contacts surface 170 of wall structure 146, with conductive layer 112 mechanically and electrically connected to conductive layer 138 by reflowing bumps or conductive paste 172. Wall structure 116 can have a similar height and width as wall structure 146, or a different height and width, e.g. less than, as wall structure 146.

An underfill material 174, such as epoxy resin, is deposited between electrical component 148 and interconnect substrate 132. The dispensing of underfill material 174 can be difficult to control. Any excess underfill material 174 flows outwardly from the perimeter of electrical component 148, including toward opening 140. Underfill material 174 should not be allowed to reach optical window 115, or optical coupler 114, as that event could cause defects. In this case, wall structure 116 contacting surface 170 of wall structure 146 acts as a barrier to impede or block excess underfill material 174 from reaching optical window 115, or optical coupler 114. Optical window 115 should remain free from dust and contamination from underfill material 174. To achieve the protection for optical window 115, the excess underfill material 174 is impeded or blocked by the combination of wall structure 116 and wall structure 146 from reaching the optical window. FIG. 3c is a top view of wall structure 116 contacting a center portion of surface 170 of wall structure 146 around optical window 115. Underfill material 174 is shown as being impeded by wall structures 116 and 146 proximate to opening 140 as the underfill barrier.

In FIG. 3d, an encapsulant or molding compound 176 is deposited over and around electrical component 148 and interconnect structure 132 using a paste printing, compressive molding, transfer molding, liquid encapsulant molding, vacuum lamination, spin coating, or other suitable applicator. Encapsulant 176 can be polymer composite material, such as epoxy resin with filler, epoxy acrylate with filler, or polymer with proper filler. Encapsulant 176 is non-conductive, provides structural support, and environmentally protects the semiconductor device from external elements and contaminants.

In FIG. 3e, temporary substrate or carrier 120 and adhesive layer 130 are removed by chemical etching, CMP, mechanical peel-off, mechanical grinding, thermal bake, UV light, or wet stripping to expose opening 140. Optical cable 177 is disposed within opening 140 to provide light 178 to optical window 115 and coupler 114. Any excess underfill material 174 flows outward from electrical assembly 148. Underfill material 174 should not be allowed to reach optical window 115, as that event could cause defects. In this case, the dual peripheral wall structures 116 and 146 act as a barrier, as respectively formed on opposing structures electrical component 148 and interconnect substrate 120, to impede or block excess underfill material 174 from reaching opening 140 and optical window 115. Wall structures 116 and 146 form a KOZ with respect to optical window 115. Note that wall structure 116 is formed on electrical device 148 and wall structure 146 is formed on interconnect structure 132. Accordingly, wall structures 116 and 146 are respectively formed on opposing electrical device 148 and interconnect structure 132. It is the dual peripheral wall structures 116 and 146, as lithography formed on opposing structures, that comes together to form the KOZ. Wall structures 116 and 146 are considered a stacked peripheral barrier.

The combination of interconnect substrate 120, electrical component 148, underfill material 174, and encapsulant 176 constitutes CPO 180. Underfill material 174 is shown as being impeded by wall structures 116 and 146 proximate to opening 140 and optical window 115, i.e., the barrier to impede or block progression of excess underfill material toward the opening and optical window, in CPO 180. The underfill barrier provided by wall structures 116 and 146 protects coupler 114 and optical window 115 from damage and defects potentially caused by the bleeding of excess underfill material 174. The underfill barrier increases process margin, capability, and yield, while reducing manufacturing costs.

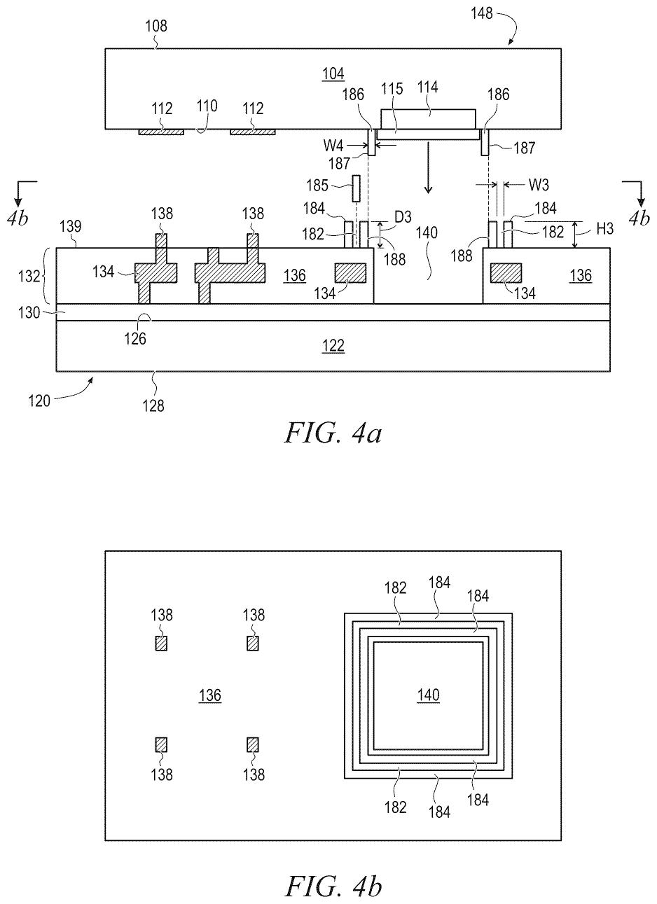

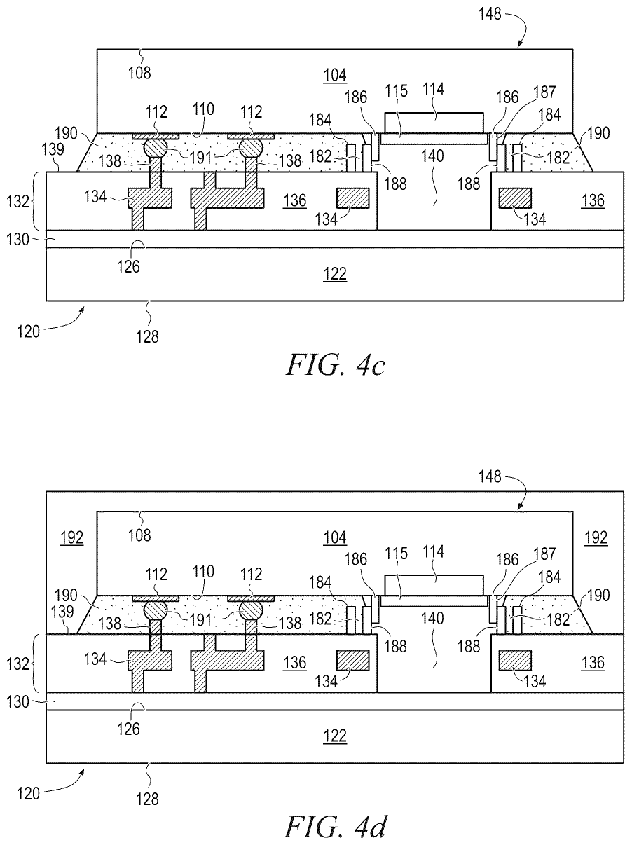

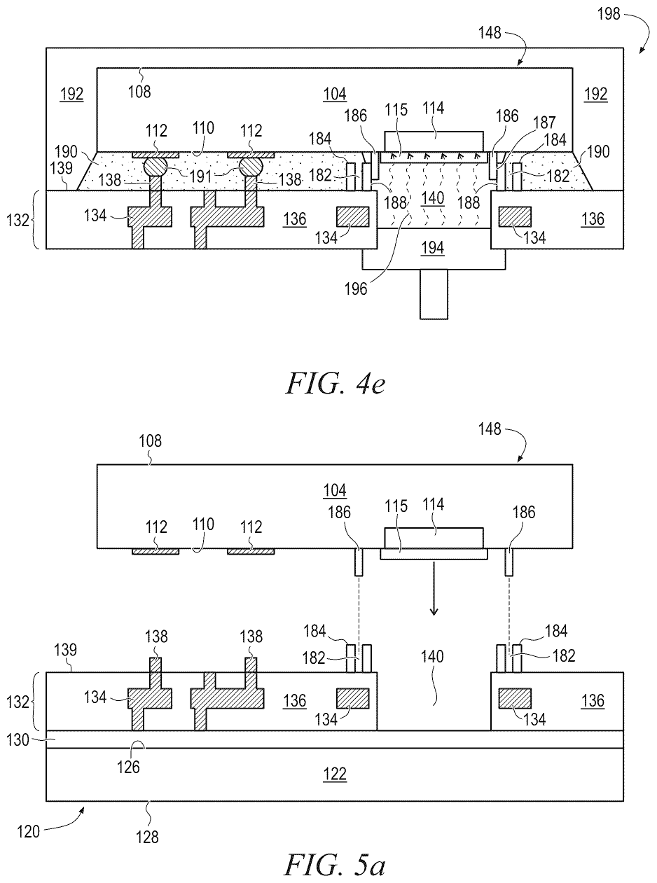

In another embodiment, continuing from FIG. 2c, a trench or channel 182 is formed in wall structure 184 using lithography 185, as shown in FIG. 4a. Wall structure 184 is similar to wall structure 146. In one embodiment, wall structure 184 has a height H3 of 15-25 μm, and trench 182 has a depth D3 of 15-25 μm and a width W3 of 15-25 μm. The width of wall structure 184 is similar to wall structure 146. Wall structure 186 has a width W4 of 10-30 μm and a height typically less than or equal to D3. Trench 182 can extend partially into or completely through wall structure 184. Wall structure 186 is formed over surface 110 of electrical component 148 around optical window 115. Wall structure 186 is made similar to wall structure 116, and wall structure 184 is made similar to wall structure 146. A top view of wall structure 186 would be similar to FIG. 2g. FIG. 4b shows a top view of trench or channel 182 formed in wall structure 184. Electrical component 148 is positioned over interconnect structure 132 using a pick and place operation with optical window 115 and wall structure 186 oriented toward opening 140 and wall structure 184. In this case, outside side surface 187 of wall structure 186 is aligned inside side surface 188 of wall structure 184. In FIG. 4c, electrical component 148 is brought into contact with interconnect structure 132, such that wall structure 186 contacts surface 188 of wall structure 184, with conductive layer 112 mechanically and electrically connected to conductive layer 138 by reflowing bumps or conductive paste 191.

An underfill material 190, such as epoxy resin, is deposited between electrical component 148 and interconnect substrate 132. The dispensing of underfill material 190 can be difficult to control. Any excess underfill material 190 flows outwardly from the perimeter of electrical component 148, including toward opening 140. Underfill material 190 should not be allowed to reach optical window 115, or optical coupler 114, as that event could cause defects. In this case, wall structure 186 extending into trench 182 of wall structure 184 acts as a barrier to impede or block excess underfill material 190 from reaching optical window 115, or optical coupler 114. Optical window 115 should remain free from dust and contamination from underfill material 190. Some underfill material 190 flows into trench 182. To achieve the protection for optical window 115, the excess underfill material 190 is impeded or blocked by the combination of wall structure 186 and wall structure 184 with trench 182 from reaching the optical window. Underfill material 190 is shown as being impeded by wall structures 186 and 184 with trench 182 proximate to opening 140 as the underfill barrier.

In FIG. 4d, an encapsulant or molding compound 192 is deposited over and around electrical component 148 and interconnect structure 132 using a paste printing, compressive molding, transfer molding, liquid encapsulant molding, vacuum lamination, spin coating, or other suitable applicator. Encapsulant 192 can be polymer composite material, such as epoxy resin with filler, epoxy acrylate with filler, or polymer with proper filler. Encapsulant 192 is non-conductive, provides structural support, and environmentally protects the semiconductor device from external elements and contaminants.

In FIG. 4e, temporary substrate or carrier 120 and adhesive layer 130 are removed by chemical etching, CMP, mechanical peel-off, mechanical grinding, thermal bake, UV light, or wet stripping to expose opening 140. Optical cable 194 is disposed within opening 140 to provide light 196 to optical window 115 and coupler 114. Any excess underfill material 190 flows outward from electrical assembly 148. Underfill material 190 should not be allowed to reach optical window 115, as that event could cause defects. In this case, the dual peripheral side surface 187 of wall structure 186 contacting side surface 188 of wall structure 184 acts as a barrier, as respectively formed on opposing structures electrical component 148 and interconnect substrate 120, to impede or block excess underfill material 190 from reaching opening 140 and optical window 115. Some underfill material 190 flows into trench 182. Wall structure 186 contacting surface 188 of wall structure 184 impedes any remaining excess underfill material 190. Wall structures 186 and 184 with trench 182 form a KOZ with respect to optical window 115. Note that wall structure 186 is formed on electrical device 148 and wall structure 184 with trench 182 is formed on interconnect structure 132. Accordingly, wall structures 186 and 184 are respectively formed on opposing electrical device 148 and interconnect structure 132. It is the dual peripheral wall structures 186 and 184, as lithography formed on opposing structures, that comes together to form the KOZ.

The combination of interconnect substrate 120, electrical component 148, underfill material 190, and encapsulant 192 constitute CPO 198. Underfill material 190 is shown as being impeded by wall structure 186 and wall structure 184 with trench 182 proximate to opening 140 and optical window 115, i.e., the barrier to impede or block progression of excess underfill material toward the opening and optical window, in CPO 198. The underfill barrier provided by wall structures 186 and 184 with trench 182 protects coupler 114 and optical window 115 from damage and defects potentially caused by the bleeding of excess underfill material 190. The underfill barrier increases process margin, capability, and yield, while reducing manufacturing costs.

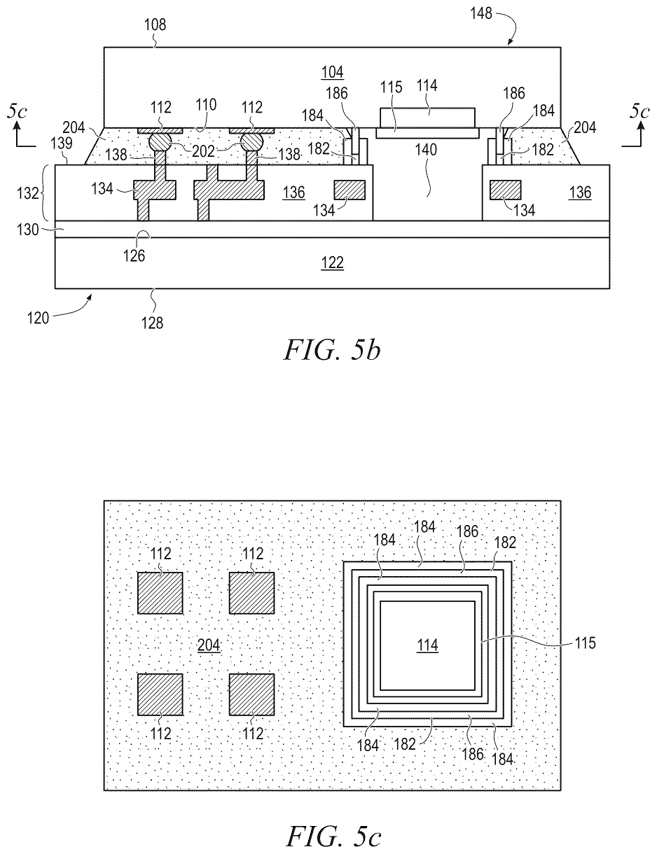

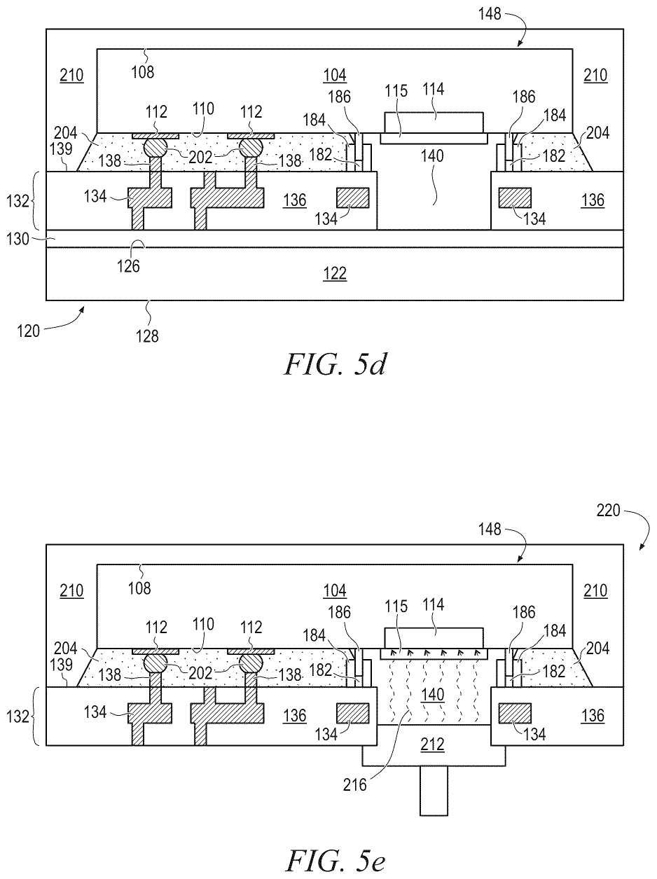

In another embodiment, continuing from FIGS. 4a-4b, electrical component 148 is positioned over interconnect structure 132 using a pick and place operation with optical window 115 and wall structure 186 oriented toward opening 140 and wall structure 184, as shown in FIG. 5a. In this case, wall structure 186 is aligned with trench 182. In FIG. 5b, electrical component 148 is brought into contact with interconnect structure 132, such that wall structure 186 extends into trench 182 of wall structure 184, with conductive layer 112 mechanically and electrically connected to conductive layer 138 by reflowing bumps or conductive paste 202.

An underfill material 204, such as epoxy resin, is deposited between electrical component 148 and interconnect substrate 132. The dispensing of underfill material 204 can be difficult to control. Any excess underfill material 204 flows outwardly from the perimeter of electrical component 148, including toward opening 140. Underfill material 204 should not be allowed to reach optical window 115, or optical coupler 114, as that event could cause defects. In this case, wall structure 186 extending into trench 182 of wall structure 184 acts as a barrier to impede or block excess underfill material 204 from reaching optical window 115, or optical coupler 114. Optical window 115 should remain free from dust and contamination from underfill material 204. To achieve the protection for optical window 115, the excess underfill material 204 is impeded or blocked by the combination of wall structure 184 and wall structure 186 extending into trench 182 from reaching the optical window. Some underfill material 204 can fill trench 182. FIG. 5c is a top view of wall structure 186 extending into trench 182 of wall structure 184 around optical window 115. Underfill material 204 is shown as being impeded by wall structures 186 in trench 182 of wall structure 184 proximate to opening 140 as the underfill barrier.

In FIG. 5d, an encapsulant or molding compound 210 is deposited over and around electrical component 148 and interconnect structure 132 using a paste printing, compressive molding, transfer molding, liquid encapsulant molding, vacuum lamination, spin coating, or other suitable applicator. Encapsulant 210 can be polymer composite material, such as epoxy resin with filler, epoxy acrylate with filler, or polymer with proper filler. Encapsulant 210 is non-conductive, provides structural support, and environmentally protects the semiconductor device from external elements and contaminants.

In FIG. 5e, temporary substrate or carrier 120 and adhesive layer 130 are removed by chemical etching, CMP, mechanical peel-off, mechanical grinding, thermal bake, UV light, or wet stripping to expose opening 140. Optical cable 212 is disposed within opening 140 to provide light 216 to optical window 115 and coupler 114. Any excess underfill material 204 flows outward from electrical assembly 148. Underfill material 204 should not be allowed to reach optical window 115, as that event could cause defects. In this case, the dual peripheral wall structure 186 extending into trench 182 of wall structure 184 acts as a barrier, as respectively formed on opposing structures electrical component 148 and interconnect substrate 120, to impede or block excess underfill material 204 from reaching opening 140 and optical window 115. Wall structure 186 disposed in trench 182 of wall structure 184 forms a KOZ with respect to optical window 115. Note that wall structure 186 is formed on electrical device 148 and wall structure 184 with trench 182 is formed on interconnect structure 132. Accordingly, wall structures 186 and 184 are respectively formed on opposing electrical device 148 and interconnect structure 132. It is the dual peripheral wall structures 186 and 184, as lithography formed on opposing structures, that come together to form the KOZ.

The combination of interconnect substrate 120, electrical component 148, underfill material 204, and encapsulant 176 constitute CPO 220. Underfill material 204 is shown as being impeded by wall structures 186 and 184 proximate to opening 140 and optical window 115, i.e., the barrier to impede or block progression of excess underfill material toward the opening and optical window, in CPO 220. The underfill barrier provided by wall structures 186 and 184 protects coupler 114 and optical window 115 from damage and defects potentially caused by the bleeding of excess underfill material 204. The underfill barrier increases process margin, capability, and yield, while reducing manufacturing costs.

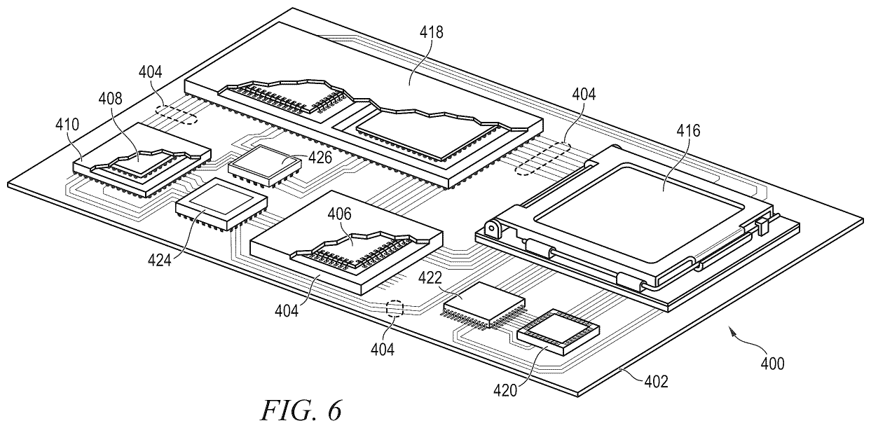

FIG. 6 illustrates electrical device 400 having a chip carrier substrate or PCB 402 with a plurality of semiconductor packages disposed on a surface of PCB 402, including CPO packages 168, 180, 198, and 220. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an electrical component including an optical region formed on the electrical component;
a first barrier formed proximate to the optical region;
an interconnect structure;
a second barrier formed on the interconnect structure, wherein the electrical component is disposed over the interconnect structure; and
an underfill material deposited under the electrical component, wherein the first barrier contacts the second barrier to impede the underfill material from reaching the optical region.

2. The semiconductor device of claim 1, wherein the first barrier includes a first wall structure and the second barrier includes a second wall structure contacting the first wall structure to impede the underfill material from reaching the optical region.

3. The semiconductor device of claim 2, wherein the first wall structure contacts a side surface of the second wall structure.

4. The semiconductor device of claim 2, further including a trench formed in the second wall structure.

5. The semiconductor device of claim 4, wherein the first wall structure extends into the trench.

6. The semiconductor device of claim 1, further including an opening formed in the interconnect structure, wherein the optical region is disposed over the opening in the interconnect structure.

7. A semiconductor device, comprising:
an electrical component including an optical region and a first barrier formed proximate to the optical region;
an interconnect structure including a second barrier formed on the interconnect structure, wherein the electrical component is disposed over the interconnect structure; and
an underfill material deposited under the electrical component, wherein the first barrier contacts the second barrier to impede the underfill material from reaching the optical region.

8. The semiconductor device of claim 7, wherein the first barrier includes a first wall structure and the second barrier includes a second wall structure contacting the first wall structure to impede the underfill material from reaching the optical region.

9. The semiconductor device of claim 8, wherein the first wall structure contacts a side surface of the second wall structure.

10. The semiconductor device of claim 8, further including a trench formed in the second wall structure.

11. The semiconductor device of claim 10, wherein the first wall structure extends into the trench.

12. The semiconductor device of claim 7, further including an opening formed in the interconnect structure.

13. The semiconductor device of claim 12, wherein the optical region is disposed over the opening in the interconnect structure.

14. A method of making a semiconductor device, comprising:
providing an electrical component including an optical region formed on the electrical component;
forming a first barrier proximate to the optical region;
providing an interconnect structure;
forming a second barrier on the interconnect structure, wherein the electrical component is disposed over the interconnect structure; and
depositing an underfill material under the electrical component, wherein the first barrier contacts the second barrier to impede the underfill material from reaching the optical region.

15. The method of claim 14, wherein the first barrier includes a first wall structure and the second barrier includes a second wall structure contacting the first wall structure to impede the underfill material from reaching the optical region.

16. The method of claim 15, wherein the first wall structure contacts a side surface of the second wall structure.

17. The method of claim 15, further including forming a trench in the second wall structure.

18. The method of claim 17, wherein the first wall structure extends into the trench.

19. The method of claim 14, further including forming an opening in the interconnect structure, wherein the optical region is disposed over the opening in the interconnect structure.

20. A method of making a semiconductor device, comprising:
providing an electrical component including an optical region and a first barrier formed proximate to the optical region;
providing an interconnect structure including a second barrier formed on the interconnect structure, wherein the electrical component is disposed over the interconnect structure; and
depositing an underfill material under the electrical component, wherein the first barrier contacts the second barrier to impede the underfill material from reaching the optical region.

21. The method of claim 20, wherein the first barrier includes a first wall structure and the second barrier includes a second wall structure contacting the first wall structure to impede the underfill material from reaching the optical region.

22. The method of claim 21, wherein the first wall structure contacts a side surface of the second wall structure.

23. The method of claim 21, further including forming a trench in the second wall structure.

24. The method of claim 23, wherein the first wall structure extends into the trench.

25. The method of claim 20, further including forming an opening in the interconnect structure, wherein the optical region is disposed over the opening in the interconnect structure.
